(19) United States
(12) Patent Application Publication
(10) Pub. No.: US 2025/0287792 A1
(43) Pub. Date: Sep. 11, 2025

(54) DISPLAY DEVICE

(71) Applicant: Japan Display Inc., Tokyo (JP)

(72) Inventors: Hayata AOKI, Tokyo (JP); Tomohiko NAGANUMA, Tokyo (JP)

(73) Assignee: Japan Display Inc., Tokyo (JP)

(21) Appl. No.: 19/062,049

(22) Filed: Feb. 25, 2025

(30) Foreign Application Priority Data
Mar. 8, 2024 (JP) 2024-035953

(51) Int. Cl. H10K 59/126; H10K 59/122; H10K 59/35

(52) U.S. Cl. CPC H10K 59/126; H10K 59/122; H10K 59/352

(57) ABSTRACT

According to one embodiment, a display device includes a first subpixel and a second subpixel that are spaced apart from each other and illuminate in colors different from each other, a rib layer, and a first light-shielding film located above the rib layer. The rib layer includes a first pixel aperture, which has a first edge and overlaps the first subpixel, and a second pixel aperture, which has a second edge and overlaps the second subpixel. The first light-shielding film includes a first aperture, which has a third edge and overlaps the first pixel aperture, and a second aperture, which has a fourth edge and overlaps the second pixel aperture. A distance between the second edge and the fourth edge is shorter than a distance between the first edge and the third edge.

### CROSS-REFERENCE TO RELATED APPLICATIONS

This application is based upon and claims the benefit of priority from Japanese Patent Application No. 2024-035953, filed Mar. 8, 2024, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. In this type of display devices, a technique which can improve display qualities is required.

### BRIEF DESCRIPTION OF THE DRAWINGS

FIG. 1 is a view showing a configuration example of a display device of the first embodiment.

FIG. 2 is a schematic plan view showing a layout example of subpixels.

FIG. 3 is a schematic cross-sectional view of a display device along III-III line in FIG. 2.

FIG. 4 is a view showing an example of a layer structure applicable to display elements.

FIG. 5 shows an example of internal emission spectra of a light emitting layer.

FIG. 6 is a schematic plan view showing components for realizing functions related to a touch panel.

FIG. 7 is a schematic plan view showing a layout example of a light-shielding film.

FIG. 8 is a schematic plan view showing pixel apertures and apertures of the light-shielding film that are shown in FIG. 7.

FIG. 9 is a schematic plan view showing a layout example of metal wires.

FIG. 10 is a schematic plan view showing pixel apertures and apertures of the metal wires shown in FIG. 9.

FIG. 11 is a schematic plan view showing an example of a pixel aperture, an aperture of the light-shielding film, and an aperture of the metal wire.

FIG. 12 is a schematic plan view showing another example of the pixel aperture, an aperture of the light-shielding film, and an aperture of the metal wire.

FIG. 13 is a schematic plan view showing yet another example of the pixel aperture, an aperture of the light-shielding film, and an aperture of the metal wire.

FIG. 14 shows an example of emission spectra.

FIG. 15 is a diagram showing relationships among angles of the subpixels and values of brightness of the respective subpixels.

FIG. 16 is a schematic cross-sectional view of a display device of the second embodiment.

FIG. 17 is a schematic plan view showing an example of pixel apertures and apertures of a light-shielding film of the second embodiment.

FIG. 18 is a schematic plan view showing another example of the pixel apertures and apertures of the light-shielding film of the second embodiment.

FIG. 19 is a schematic cross-sectional view of a display device of the third embodiment.

FIG. 20 is a schematic plan view showing an example of pixel apertures and apertures of a metal wire of the third embodiment.

FIG. 21 is a schematic plan view showing another example of the pixel apertures and the apertures of the metal wire of the third embodiment.

### DETAILED DESCRIPTION

In general, according to one embodiment, a display device includes: a first subpixel and a second subpixel that are spaced apart from each other and illuminate in colors different from each other; a rib layer; and a first light-shielding film located above the rib layer. The rib layer includes: a first pixel aperture, which has a first edge parallel to a first direction and overlaps the first subpixel; and a second pixel aperture, which has a second edge parallel to the first direction and overlaps the second subpixel. The first light-shielding film includes: a first aperture, which has a third edge parallel to the first direction and overlaps the first pixel aperture; and a second aperture, which has a fourth edge parallel to the first direction and overlaps the second pixel aperture. A distance between the second edge and the fourth edge along a second direction intersecting the first direction is shorter than a distance between the first edge and the third edge along the second direction.

Embodiments can provide a display device capable of improving display qualities.

Embodiments will be described with reference to the accompanying drawings. The disclosure is merely an example, and

proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X axis, a Y axis and a Z axis orthogonal to each other are described to facilitate understanding as needed. A direction along the X axis is referred to as an X direction (a first direction) and a direction along the Y axis is referred to as a Y direction (a second direction), and a direction along the Z axis is referred to as a Z direction. When various elements are viewed parallel to the Z direction, the appearance is defined as a plan view.

The display device of each embodiment is an organic electroluminescent display device comprising organic light emitting diodes (OLED) as display elements, and could be mounted on various types of electronic devices such as a television, a personal computer, a vehicle-mounted device, a tablet, a smartphone, a mobile phone, and a wearable terminal.

### First Embodiment

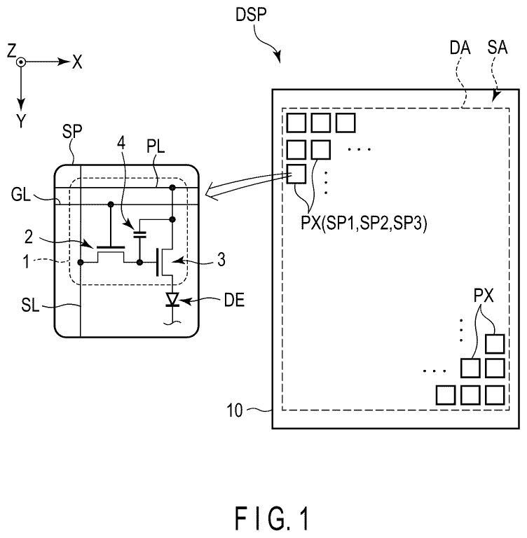

FIG. 1 is a view showing a configuration example of a display device DSP of the first embodiment. The display device DSP comprises an insulating substrate 10. The substrate 10 has a display area DA which displays images and a surrounding area SA around the display area DA. The substrate 10 may be glass or a flexible resinous film.

The substrate 10 in the present embodiment has a rectangular shape in plan view. The shape of the substrate 10 in plan view is not limited to a rectangle and may be another shape such as a square, a circle or an oval.

The display area DA comprises a plurality of pixels PX arranged in a matrix in the X direction and the Y direction. Each pixel PX includes a plurality of subpixels SP which display different colors. The present embodiment assumes a case where each pixel PX includes a subpixel SP1 (a first subpixel) illuminating in blue, a subpixel SP2 (a second subpixel) illuminating in green, and a subpixel SP3 (a third subpixel) illuminating in red. However, each pixel PX may include a subpixel SP that illuminates in another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1.

The pixel circuit 1 comprises a pixel switch 2, a drive transistor 3, and a capacitor 4. The pixel switch 2 and the drive transistor 3 are, for example, switching elements constituted by thin-film transistors. The display area DA has a plurality of

scanning lines GL supplying scanning signals to the pixel circuit 1 of each subpixel SP, a plurality of signal lines SL supplying video signals to the pixel circuit 1 of each subpixel SP, and a plurality of power lines PL. In the example of FIG. 1, the scanning lines GL and the power lines PL extend in the X direction, and the signal lines SL extend in the Y direction.

A gate electrode of the pixel switch 2 is connected to the scanning line GL. A source electrode of the pixel switch 2 is connected to the signal line SL. A drain electrode of the pixel switch 2 is connected to a gate electrode of the drive transistor 3 and the capacitor 4. A source electrode of the drive transistor 3 is connected to the power line PL and the capacitor 4. A drain electrode of the drive transistor 3 is connected to the display element DE.

The configuration of the pixel circuit 1 is not limited to the example of the figure. For example, the pixel circuit 1 may comprise more thin-film transistors and capacitors.

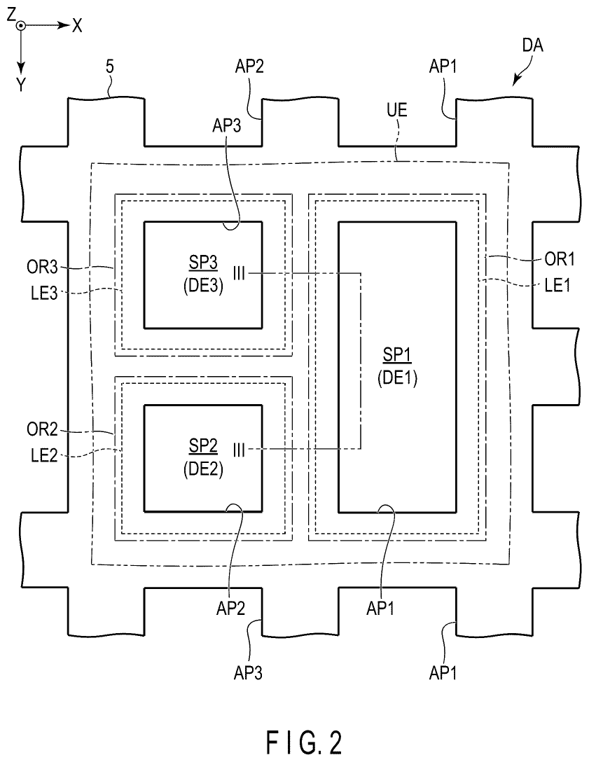

FIG. 2 is a schematic plan view showing a layout example of the subpixels SP1, SP2, and SP3. The subpixels SP1, SP2, and SP3 are spaced apart from one another. In the example of FIG. 2, the subpixels SP2 and SP3 are arranged with the subpixel SP1 in the X direction. Further, the subpixels SP2 and SP3 are arranged in the Y direction.

In this layout of the subpixels SP1, SP2 and SP3, the display area DA has a column in which the subpixels SP2 and SP3 are alternately arranged in the Y direction and a column in which the plurality of subpixels SP1 are repeatedly arranged in the Y direction. These columns are alternately arranged in the X direction. The layout of the subpixels SP1, SP2, and SP3 is not limited to the example of FIG. 2.

The display area DA has a rib layer 5. The rib layer 5 includes pixel apertures AP1, AP2, and AP3 (first to third pixel apertures) respectively overlapping the subpixels SP1, SP2, and SP3. In the example of FIG. 2, the pixel aperture AP1 is greater than the pixel apertures AP2 and AP3; the pixel aperture AP2 has the same size as the pixel aperture AP3. That is, the aperture ratio of the subpixel SP1 is greater than the aperture ratio of each of the subpixels SP2 and SP3; the subpixel SP2 and the subpixel SP3 have the same aperture ratio. The size of each of the pixel apertures AP1, AP2, and AP3 is not limited to this example. For example, the pixel aperture AP2 may be greater than the pixel aperture AP3.

The subpixel SP1 comprises a lower electrode LE1 and an organic layer OR1 each overlapping the pixel aperture AP1. The subpixel SP2 comprises a lower electrode LE2 and an organic layer OR2 each overlapping the pixel aperture AP2. The subpixel SP3 comprises a lower electrode LE3 and an organic layer OR3 each overlapping the pixel aperture AP3. The subpixels SP1, SP2, and SP3 comprise an upper electrode UE. The subpixels SP1, SP2, and SP3 share the same upper electrode UE.

Portions that overlap the pixel aperture AP1 of the lower electrode LE1, the organic layer OR1, and the upper electrode UE constitute a display element DE1 of the subpixel SP1. Portions that overlap the pixel aperture AP2 of the lower electrode LE2, the organic layer OR2, and the upper electrode UE constitute a display element DE2 of the subpixel SP2. Portions that overlap the pixel aperture AP3 of the lower electrode LE3, the organic layer OR3, and the upper electrode UE constitute a display element DE3 of the subpixel SP3. Each of the display elements DE1, DE2, and DE3 may further include a cap layer to be described later. The rib layer 5 has a grating shape in plan view and surrounds each of the display elements DE1, DE2, and DE3.

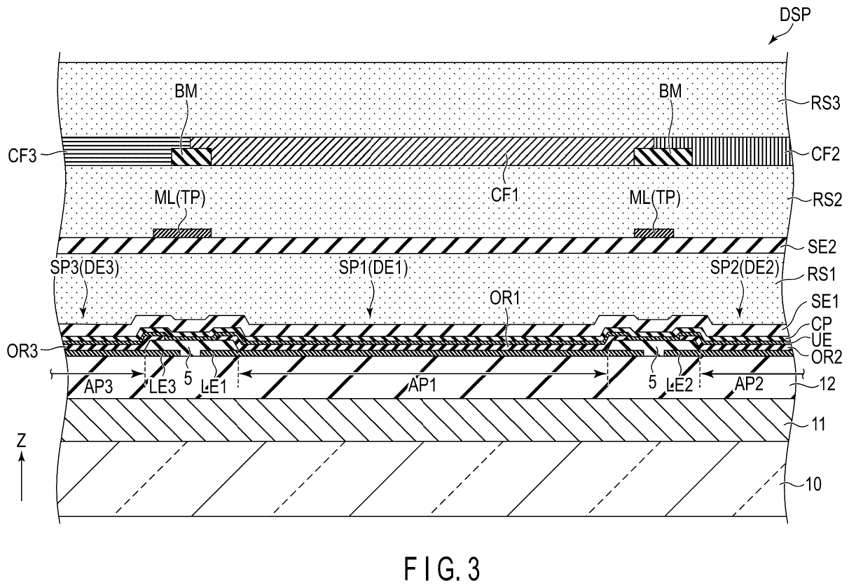

FIG. 3 is a schematic cross-sectional view of the display device DSP along III-III line in FIG. 2. A circuit layer 11 is provided on the substrate 10 described above. The circuit layer 11 includes various circuits and lines such as the pixel circuit 1, the scanning lines GL, the signal lines SL, and the power lines PL shown in FIG. 1. The circuit layer 11 is covered with an organic insulating layer 12. The organic insulating layer 12 functions as a planarization film which planarizes irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. End portions of the lower electrodes LE1, LE2, and LE3 are covered with the rib layer 5. Although not shown in the cross-section in FIG. 3, the lower electrodes LE1, LE2, and LE3 are connected to the pixel circuit 1 (the drain electrode of the drive transistor 3 shown in FIG. 1) of the circuit layer 11 through respective contact holes provided in the organic insulating layer 12.

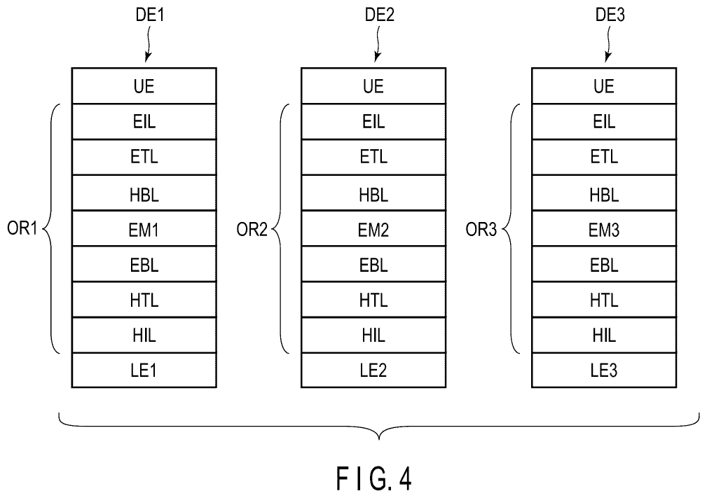

The organic layer OR1 covers the lower electrode LE1 through the pixel aperture AP1. The organic layer OR2 covers the lower electrode LE2 through the pixel aperture AP2. The organic layer OR3 covers the lower electrode LE3 through the pixel aperture AP3. In the example of FIG. 3, the organic layers OR1, OR2, and OR3 are spaced apart from one another. Each of function layers such as a hole-injection layer to be described later (a hole-injection layer HIL shown in FIG. 4) may be continuous over and shared with the organic layers OR1, OR2, and OR3.

The upper electrode UE covers the organic layers OR1, OR2, and OR3 and faces the lower electrodes LE1, LE2, and LE3. In the example of FIG. 3, the upper electrode UE overlaps the rib layer 5 between the organic layer OR1 and the organic layer OR2 and between the organic layer OR1 and the organic layer OR3.

The display elements DE1, DE2, and DE3 include a cap layer CP covering the upper electrode UE. In the example of FIG. 3, the cap layer CP is shared by the display elements DE1, DE2, and DE3. The cap layer CP functions as an optical adjustment layer for improving extraction efficiency of light beams from the organic layers OR1, OR2, and OR3. For example, the cap layer CP is constituted by a stacked layer body having multiple transparent layers with different refractive indexes. The thicknesses of the cap layer CP may be different for the respective display elements DE1, DE2, and DE3 or may be the same for the display elements DE1, DE2, and DE3. The display elements DE1, DE2, and DE3 may not share one cap layer CP. Alternatively, cap layers CP spaced apart from each other may be provided for the respective display elements DE1, DE2, and DE3. The subpixels SP1, SP2, and SP3 have a

sealing layer SE1 covering the cap layer CP. The sealing layer SE1 is covered with a resin layer RS1. The resin layer RS1 is covered with a sealing layer SE2. The sealing layer SE2 is covered with a resin layer RS2.

In the example of FIG. 3, a metal wire ML (a second light-shielding film) constituting a touch panel electrode TP is provided on the second sealing layer SE2. The metal wire ML is provided above the rib layer 5 and extends along the rib layer 5. The metal wire ML is covered with the resin layer RS2.

In the example of FIG. 3, the color filters CF1, CF2, and CF3 are provided on the resin layer RS2. The color filters CF1, CF2, and CF3 are provided above the rib layer 5. The color filter CF1 is provided above the display element DE1. For example, the color filter CF1 is formed of a blue-colored resin material. The color filter CF2 is provided above the display element DE2. For example, the color filter CF2 is formed of a green-colored resin material. The color filter CF3 is provided above the display element DE3. For example, the color filter CF3 is formed of a red-colored resin material.

In the example of FIG. 3, a light-shielding film BM (a first light-shielding film) is provided on the resin layer RS2. The light-shielding film BM is provided above the rib layer 5 and the metal wire ML, overlaps the rib layer 5 and the metal wire ML in the Z direction, and extends along the rib layer 5 and the metal wire ML. The light-shielding film BM is farther from the organic layers OR1, OR2, and OR3 in the Z direction than the metal wire ML is. The light-shielding film BM contacts the color filters CF1, CF2, and CF3 and is covered with the color filters CF1, CF2, and CF3. For example, the light-shielding film BM is formed of a resin material. The resin layer RS2 is located between the light-shielding film BM and the metal wire ML and contacts the light-shielding film BM and the metal wire ML. The metal wire ML is located between the rib layer 5 and the light-shielding film BM and overlaps the rib layer 5 and the light-shielding film BM in the Z direction.

The color filters CF1, CF2, and CF3 are covered with a resin layer RS3. The resin layers RS1, RS2, and RS3 and the sealing layer SE2 are continuously provided in at least the entire display area DA and partially extend in the surrounding area SA as well. The light-shielding film BM may be located between the resin layer RS3 and the respective color filters CF1, CF2, and CF3.

A cover member such as a polarizer, a protective film, and a cover glass may be further provided above the resin layer RS3. This cover member may be attached to the resin layer RS3 via, for example, an adhesive layer such as an optical clear adhesive (OCA).

The organic insulating layer 12 is formed of an organic insulating material, such as a polyimide. Each of the rib layer 5 and the sealing layers SE1 and SE2 is formed of an inorganic insulating material, such as a silicon nitride (SiNx), a silicon oxide (SiOx), and a silicon oxynitride (SiON). For example, the rib layer 5 is formed of a silicon oxynitride, and each of the sealing layers SE1 and SE2 is formed of a silicon nitride. The rib layer 5 may be formed of an organic insulating material. Each of the resin layers RS1, RS2, and RS3 is formed of, for example, a resinous material (an organic insulating material), such as an epoxy resin or an acrylic resin.

Each of the lower electrodes LE1, LE2, and LE3 has a reflective layer and a pair of conductive oxide layers respectively covering the upper and lower surfaces of the reflective layer. The reflective layer is formed of, for example, a metallic material having excellent light-reflecting properties, such as silver. Each of the conductive oxide layers can be formed of, for example, a transparent conductive oxide, such as an indium tin oxide (ITO), an indium zinc oxide (IZO), and an indium gallium zinc oxide (IGZO).

The upper electrode UE is formed of, for example, a metal material such as an alloy of magnesium and silver (MgAg). For example, the lower electrodes LE1, LE2, and LE3 correspond to anodes, and the upper electrode UE corresponds to a cathode.

The metal wire ML is composed of a metal material. For example, the metal wire ML includes a stacked layer structure of titanium (Ti), aluminum (Al), and titanium. The metal wire ML may have a stacked layer structure of other metal materials or a single-layer structure.

FIG. 4 is a view showing examples of layer structures applicable to the display elements DE1, DE2, and DE3. For example, the lower electrodes LE1, LE2, and LE3 correspond to anodes, and the upper electrodes UE corresponds to a cathode.

The organic layer OR1 comprises a hole injection layer HIL, a hole transport layer HTL, an electron blocking layer EBL, a light emitting layer EM1, a hole blocking layer HBL, an electron transport layer ETL, and an electron injection layer EIL. The hole injection layer HIL is provided on the lower electrode LE1. The hole transport layer HTL is provided on the hole injection layer HIL. The electron blocking layer EBL is provided on the hole transport layer HTL. The light emitting layer EM1 is provided on the electron blocking layer EBL. The hole blocking layer HBL is provided on the light emitting layer EM1. The electron transport layer ETL is provided on the hole blocking layer HBL. The electron injection layer EIL is provided on the electron transport layer ETL. The upper electrode UE is provided on the electron injection layer EIL. The light emitting layer EM1 is formed of a material which emits light beams in a blue wavelength range.

If necessary, the organic layer OR1 may include other function layers, such as a carrier generation layer in addition to the above function layers. Alternatively, the organic layer OR1 may exclude at least one of the above function layers.

In the display element DE2, the organic layer OR2 between the lower electrode LE2 and the upper electrode UE comprises a light emitting layer EM2 instead of the light emitting layer EM1. Except this point, the display element DE2 and the display element DE1 have the same configuration. In the display element DE3, the organic layer OR3 between the lower electrode LE3 and the upper electrode UE comprises a light emitting layer EM3 instead of the light emitting layer EM1. Except this point, the display element DE3 and the display element DE1 have the same configuration. The light emitting layer EM2 is formed of a material which emits light beams in the green wavelength range. The light emitting layer EM3 is formed of a material which emits light beams in the red wavelength range.

Each of function layers such as the hole injection layer HIL, the hole transport layer HTL, the electron blocking layer EBL, the hole blocking layer HBL, the electron transport layer ETL, and the electron injection layer EIL may be a common layer shared by the organic layers OR1, OR2, and OR3. Alternatively, each of these layers may be divided into layers spaced apart from each other. Each of the thickness of the function layers including the hole injection layer HIL, the hole transport layer HTL, the electron blocking layer EBL, the hole blocking layer HBL, the electron transport layer ETL, and the electron injection layer EIL may be constant for the display elements DE1, DE2, and DE3 or may be different for the display elements DE1, DE2, and DE3.

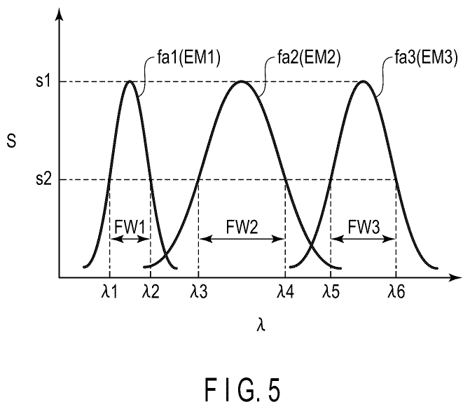

FIG. 5 shows an example of an internal emission spectrum of each of the light emitting layers EM1, EM2, and EM3. A graph in FIG. 5 has a horizontal axis indicative of wavelengths λ and a vertical axis indicative of spectrum strengths S. Curved lines fa1, fa2, and fa3 respectively indicate internal emission spectra of light emitting layers EM1, EM2, and EM3. The internal emission spectrum of each of the light emitting layers EM1, EM2, and EM3 depends on its light emitting material. The internal emission spectrum of each of the light emitting layers EM1, EM2, and EM3 depends on a photo luminescence (PL) spectrum of its light emitting material.

The followings are a comparison of half widths FW1, FW2, and FW3 of the internal emission spectra of the respective light emitting layers EM1, EM2, and EM3. Here, half widths correspond to a width of the wavelength at which the spectrum strength of internal emission spectrum is the half of the maximum value.

In the example of FIG. 5, a spectrum strength s1 is the maximum value of the spectrum strengths S of the internal emission spectra of the light emitting layers EM1, EM2, and EM3. In FIG. 5, the light emitting layers EM1, EM2, and EM3 have the same spectrum strength s1; they may have different spectrum strengths s1. A spectrum strength s2 is the half of the spectrum strength s1 (s2=s1/2).

Wavelengths of the internal emission spectra of the light emitting layer EM1 at the spectrum strength s2 are wavelengths λ1 and λ2. Thus, the half width FW1 of the internal emission spectrum of the light emitting layer EM1 corresponds to a difference between the wavelength λ2 and the wavelength λ1 (FW1=λ2−λ1).

Wavelengths of the internal emission spectra of the light emitting layer EM2 at the spectrum strength s2 are wavelengths λ3 and λ4. Thus, the half width FW2 of the internal emission spectrum of the light emitting layer EM2 corresponds to a difference between the wavelength λ4 and the wavelength λ3 (FW2=λ4−λ3).

Wavelengths of the internal emission spectra of the light emitting layer EM3 at the spectrum strength s2 are wavelengths λ5 and λ6. Thus, the half width FW3 of the internal emission spectrum of the light emitting layer EM3 corresponds to a difference between the wavelength λ6 and the wavelength λ5 (FW3=λ6−λ5).

In the example of FIG. 5, the half width FW1 is smaller than each of the half widths FW2 and FW3(FW1<FW2, FW3). The half width FW3 is greater than the half width FW1 and is smaller than the half width FW2 (FW1<FW3 21 FW2). The sizes of the half widths FW1, FW2, and FW3 are not limited to this example. For example, the half widths FW2 and FW3 are equivalent to each other.

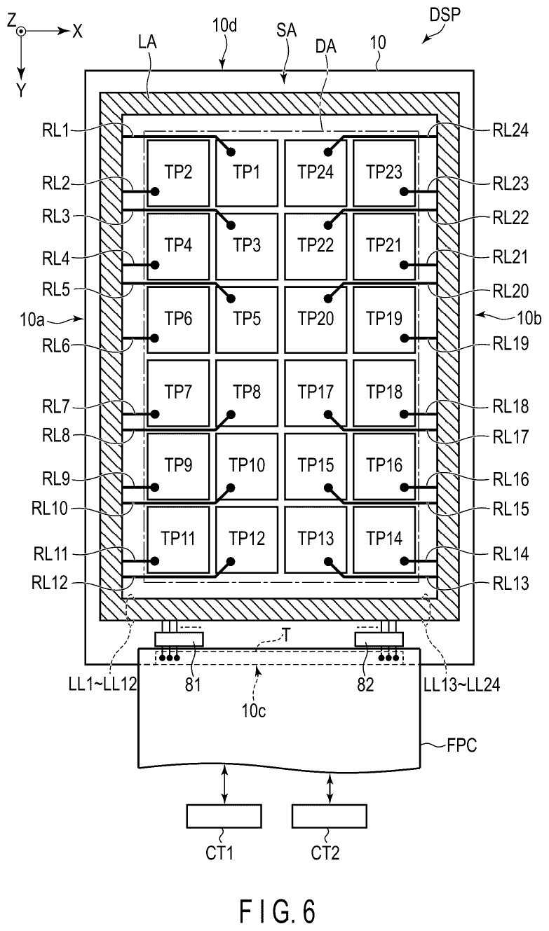

FIG. 6 is a schematic plan view showing components for realizing functions related to a touch panel. The substrate 10 has end portions 10a, 10b, 10c, and 10d. The end portions 10a and 10b extend to be parallel to the Y direction. The end portions 10c and 10d extend to be parallel to the X direction.

The display device DSP comprises a terminal portion T provided in the surrounding area SA. The terminal portion T is provided between the display area

DA and the end portion 10c. In the example of FIG. 6, the terminal portion T is connected to a flexible printed circuit FPC.

The display area DA has a plurality of touch panel electrodes TP. In the example of FIG. 6, 24 touch panel electrodes TP (TP1 to TP24) are arranged in a matrix (six rows x four columns). The touch panel electrodes TP1 to TP12 are located in the left-half of the display area DA; the touch panel electrodes TP13 to TP24 are located in the right-half of the display area DA. The number of the touch panel electrodes TP and their arrangement are not limited to this example.

The surrounding area SA has a wiring area LA for connecting the touch panel electrodes TP with the terminal portion T. The wiring area LA includes lead lines LL (LL1 to LL24) and surrounds the display area DA. The number of the lead lines is the same as the number of the touch panel electrodes TP.

The lead lines LL1 to LL12 respectively connected to the touch panel electrodes TP1 to TP12 are arranged to pass through the region between the display area DA and the end portion 10a. The lead lines LL13 to LL24 respectively connected to the touch panel electrodes TP13 to TP24 are arranged to pass through the region between the display area DA and the end portion 10b.

Relay wires RL (RL1 to RL24) connect the wire area LA with the touch panel electrodes TP1 to TP24, respectively. More specifically, the relay wires RL1 to RL12 respectively connect the touch panel electrodes TP1 to TP12 with the lead wires LL1 to LL12; the relay wires RL13 to RL24 respectively connect the touch panel electrodes TP13 to TP24 with the lead wires LL13 to LL24.

A connection unit 81 connects the lead wires LL1 to LL12 with the terminal portion T. A connection unit 82 connects the lead wires LL13 to LL24 with the terminal portion T.

For example, the touch panel electrodes TP1 to TP12, the lead wires LL1 to LL12, the relay wires RL1 to RL12, and the connection unit 81 are arranged symmetrically around the centerline parallel to the Y direction of the display device DSP with the touch panel electrodes TP 13 to TP24, the lead wires LL13 to LL24, the relay wires RL13 to RL24, and the connection unit 82.

An end of the flexible printed circuit FPC is connected to the terminal portion T via a conductive adhesive and the like. The other end of the flexible printed circuit FPC is connected to a substrate of an electronic device on which the display device DSP is mounted. Video signals and power sources necessary for image displaying are supplied to the display device DSP via the flexible printed circuit FPC.

The display device DSP further comprises a display controller CT1 for controlling image displaying, and a detection controller CT2 for controlling touch detections. The display controller CT1 and the detection controller CT2 are for example constituted by ICs and are mounted on the flexible printed circuit FPC. The display controller CT1 and the detection controller CT2 may be provided on different flexible printed circuits. These flexible printed circuits each may be connected to the terminal portion T.

The present embodiment assumes a case where the touch panel electrodes TP1 to TP24 constitute a capacitive touch panel. For example, when objects, such as a user's finger and the like contact or approach the display area DA, the detection controller CT2 identifies a position that has been contacted or approached by the object based on changes in the capacitance of the touch panel electrodes TP1 to TP24. Such a system is called a self-capacitive sensing.

A mutual capacitive sensing may also be adopted as an object detection system. In that case, the display area DA includes a drive electrode in addition to the touch panel electrodes TP1 to TP24. An object contacting or approaching the display area DA affects a magnetic field between the touch panel electrodes TP1 to TP24 and change the capacity between the touch panel electrodes TP1 to TP24 and the drive electrode. The detection controller CT2 identifies the position which has been contacted or approached by the object based on this change in the capacity.

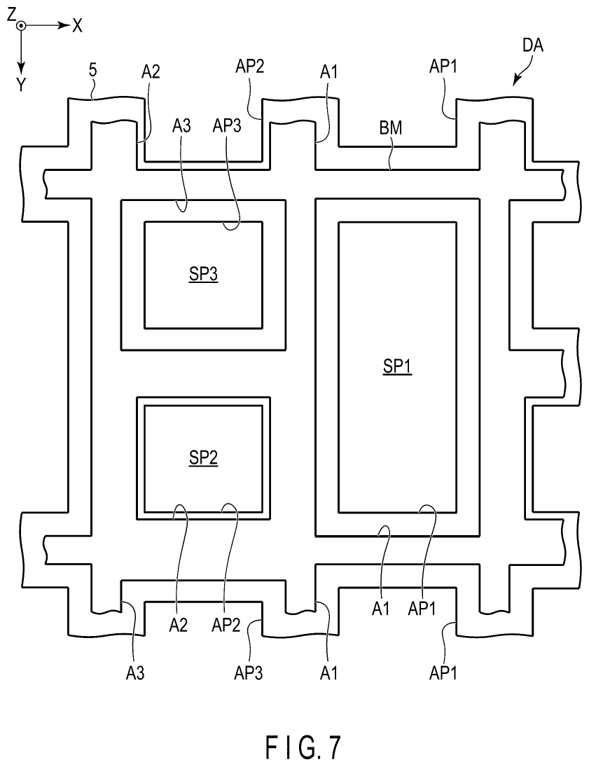

FIG. 7 is a schematic plan view showing a layout example of the light-shielding film BM. The light-shielding film BM is formed in a grating shape and surrounds each of the subpixels SP1, SP2, and SP3. The light-shielding film BM has apertures A1, A2, and A3 (first to third apertures) respectively overlapping the pixel apertures AP1, AP2, and AP3. The display area DA has a column in which the apertures A2 and A3 are alternately arranged in the Y direction and a column in which the plurality of apertures A1 are repeatedly arranged in the Y direction. These columns are alternately arranged in the X direction.

The example of FIG. 7 has the aperture A1 greater than the apertures A2 and A3 and has the aperture A3 greater than the aperture A2. The periphery of the aperture A1 does not overlap the pixel aperture AP1 in plan view. Similarly, the periphery of the aperture A2 does not overlap the pixel aperture AP2 in plan view. The periphery of the aperture A3 does not overlap the pixel aperture AP3 in plan view.

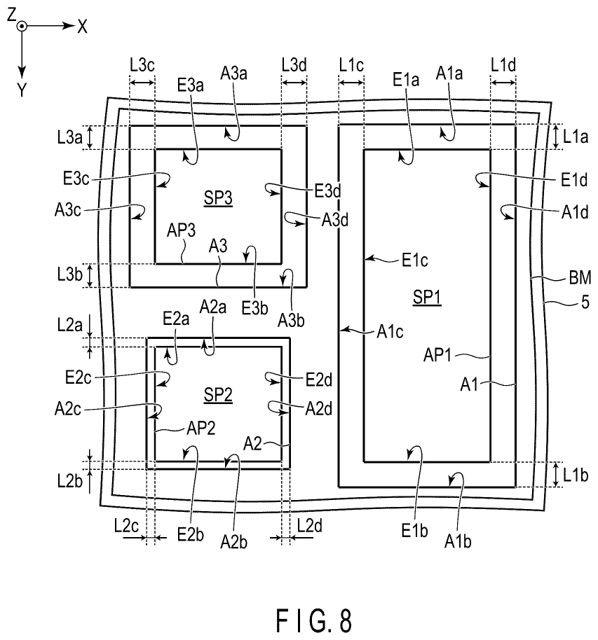

FIG. 8 is a schematic plan view showing the pixel apertures AP1, AP2, and AP3 and the apertures A1, A2, and A3 of the light-shielding film BM shown in FIG. 7. As shown, the periphery of the pixel aperture AP1 is divided into and defined as edges E1a, E1b, E1c, and E1d (first edges), the periphery of the pixel aperture AP2 is divided into and defined as edges E2a, E2b, E2c, and E2d (second edges), and the periphery of the pixel aperture AP3 is divided into and defined as edges E3a, E3b, E3c, and E3d (fifth edges). The edges E1a, E1b, E2a, E2b, E3a, and E3b are parallel to the X direction. The edges E1c, E1d, E2c, E2d, E3c, and E3d are parallel to the Y direction.

Similarly, as shown, the periphery of the aperture A1 is divided into and defined as edges A1a, A1b, A1c, and A1d (third edges), the periphery of the aperture A2 is divided into and defined as edges A2a, A2b, A2c, and A2d (fourth edges), and the periphery of the aperture A3 is divided into and defined as edges A3a, A3b, A3c, and A3d (sixth edges). The edges A1a, A1b, A2a, A2b, A3a, and A3b are parallel to the X direction. The edges A1c, A1d, A2c, A2d, A3c, and A3d are parallel to the Y direction.

Here, a distance between the edge E1a of the pixel aperture AP1 and the edge A1a of the aperture A1 along the Y direction is defined as a distance L1a. Similarly, a distance between the edge E1b and the edge A1b along the Y direction is defined as a distance L1b, a distance between the edge E1c and the edge A1c along the X direction is defined as a distance L1c, and a distance between the edge E1d and the edge A1d along the X direction is defined as a distance L1d.

In addition, a distance between the edge E2a of the pixel aperture AP2 and the edge A2a of the aperture A2 along the Y direction is defined as a distance L2a. Similarly, a distance between the edge E2b and the edge A2b along the Y direction is defined as a distance L2b, a distance between the edge E2c and the edge A2c along the X direction is defined as a distance L2c, and a distance between the edge E2d and the edge A2d along the X direction is defined as a distance L2d.

In addition, a distance between the edge E3a of the pixel aperture AP3 and the edge A3a of the aperture A3 along the Y direction is defined as a distance L3a. Similarly, a distance between the edge E3b and the edge A3b along the Y direction is defined as a distance L3b, a distance between the edge E3c and the edge A3c along the X direction is defined as a distance L3c, and a distance between the edge E3d and the edge A3d along the X direction is defined as a distance L3d.

In the example of FIG. 8, the distances L1a, L1b, L1c, and L1d have the same length (L1a=L1b =L1c=L1d). Similarly, the distances L2a, L2b, L2c, and L2d have the same length (L2a =L2b =L2c =L2d); the distances L3a, L3b, L3c, and L3d have the same length (L3a =L3b =L3c =L3d). The magnitude relationships among the distances L1a to L1d, L2a to L2d, and L3a to L3d are not limited to this example.

In the example of FIG. 8, the distances L1a and L3a have the same length (L1a=L3a). Similarly, the distances L1b and L3b have the same length (L1b=L3b), the distances L1c and L3c have the same length (L1c =L3c), and the distances L1d and L3d have the same length (L1d =L3d). The magnitude relationships among the distances L1a to L1d and L3a to L3d is are not limited to this example.

The distance L2a is shorter than each of the distances L1a and L3a (L2a <L1a, L3a). Similarly, the distance L2b is shorter than the distances L1b and L3b (L2b <L1b, L3b), the distance L2c is shorter than the distances L1c and L3c (L2c <L1c, L3c), and the distance L2d is shorter than the distances L1d and L3d (L2d <L1d, L3d).

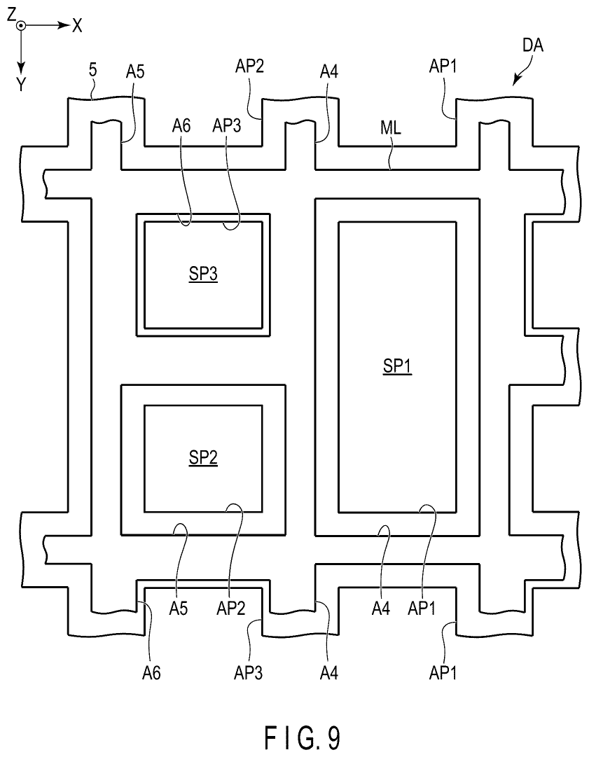

FIG. 9 is a schematic plan view showing a layout example of the metal wire ML. The metal wire ML is formed in a grating shape and surrounds each of the subpixels SP1, SP2, and SP3. The metal wire ML has apertures A4, A5, and A6 (fourth to sixth apertures) respectively overlapping the pixel apertures AP1, AP2, and AP3. The display area DA has a column in which the apertures A5 and A6 are alternately arranged in the Y direction and a column in which the plurality of apertures A4 are repeatedly arranged in the Y direction. These columns are alternately arranged in the X direction.

The example of FIG. 9 has the aperture A4 greater than the apertures A5 and A6 and has the aperture A5 greater than the aperture A6. The periphery of the aperture A4 does not overlap the pixel aperture AP1 in plan view. Similarly, the periphery of the aperture A5 does not overlap the pixel aperture AP2 in plan view. The periphery of the aperture A6 does not overlap the pixel aperture AP3 in plan view.

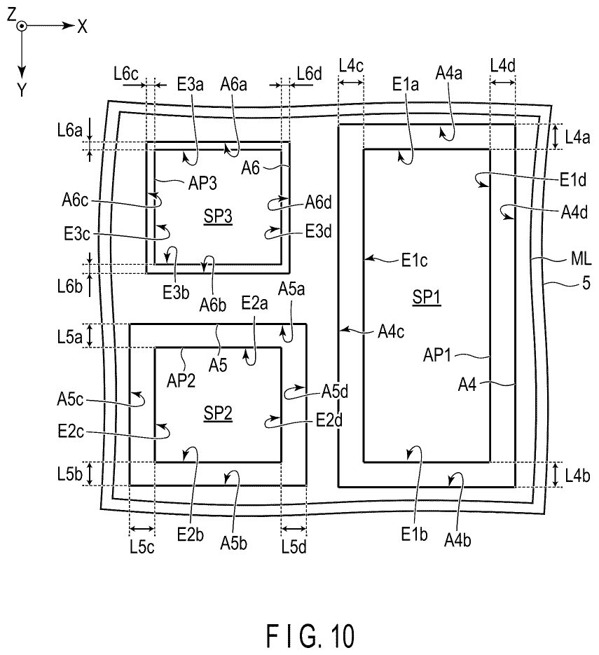

FIG. 10 is a schematic plan view showing the pixel apertures AP1, AP2, and AP3 and the apertures A4, A5, and A6 of the metal wire ML shown in FIG. 9. As shown, the periphery of the aperture A4 is divided into and defined as edges A4a, A4b, A4c, and A4d (seventh edges), the periphery of the aperture A5 is divided into and defined as edges A5a, A5b, A5c, and A5d (eighth edges), and the periphery of the aperture A6 is divided into and defined as edges A6a, A6b, A6c, and A6d (ninth edges). The edges A4a, A4b, A5a, A5b, A6a, and A6b are parallel to the X direction. The edges A4c, A4d, A5c, A5d, A6c, and A6d are parallel to the Y direction.

Here, a distance between the edge E1a of the pixel aperture AP1 and the edge A4a of the aperture A4 along the Y direction is defined as a distance L4a. Similarly, a distance between the edge E1b and the edge A4b along the Y direction is defined as a distance L4b, a distance between the edge E1c and the edge A4c along the X direction is defined as a distance L4c, and a distance between the edge E1d and the edge A4d along the X direction is defined as a distance L4d.

In addition, a distance between the edge E2a of the pixel aperture AP2 and the edge A5a of the aperture A5 along the Y direction is defined as a distance L5a. Similarly, a distance between the edge

E2b and the edge A5b along the Y direction is defined as a distance L5b, a distance between the edge E2c and the edge A5c along the X direction is defined as a distance L5c, and a distance between the edge E2d and the edge A5d along the X direction is defined as a distance L5d.

In addition, a distance between the edge E3a of the pixel aperture AP3 and the edge A6a of the aperture A6 along the Y direction is defined as a distance L6a. Similarly, a distance between the edge E3b and the edge A6b along the Y direction is defined as a distance L6b, a distance between the edge E3c and the edge A6c along the X direction is defined as a distance L6c, and a distance between the edge E3d and the edge A6d along the X direction is defined as a distance L6d.

In the example of FIG. 10, the distances L4a, L4b, L4c, and L4d have the same length (L4a=L4b=L4c=L4d). Similarly, the distances L5a, L5b, L5c, and L5d have the same length (L5a =L5b =L5c =L5d); the distances L6a, L6b, L6c, and L6d have the same length (L6a =L6b =L6c =L6d). The magnitude relationships among the distances L4a to L4d, La to L5d, and L6a to L6d are not limited to this example.

In the example of FIG. 10, the distances L4a and La have the same length (L4a =L5a). Similarly, the distances L4b and L5b have the same length (L4b=L5b), the distances L4c and L5c have the same length (L4c =L5c), and the distances L4d and L5d have the same length (L4d =L5d). The magnitude relationships among the distances L4a to L4d and L5a to L5d are not limited to this example.

The distance L6a is shorter than each of the distances L4a and L5a (L6a<L4a, L5a). Similarly, the distance L6b is shorter than the distances L4b and L5b (L6b<L4b, L5b), the distance L6c is shorter than the distances L4c and L5c (L6c <L4c, L5c), and the distance L6d is shorter than the distances L4d and L5d (L6d <L4d, L5d).

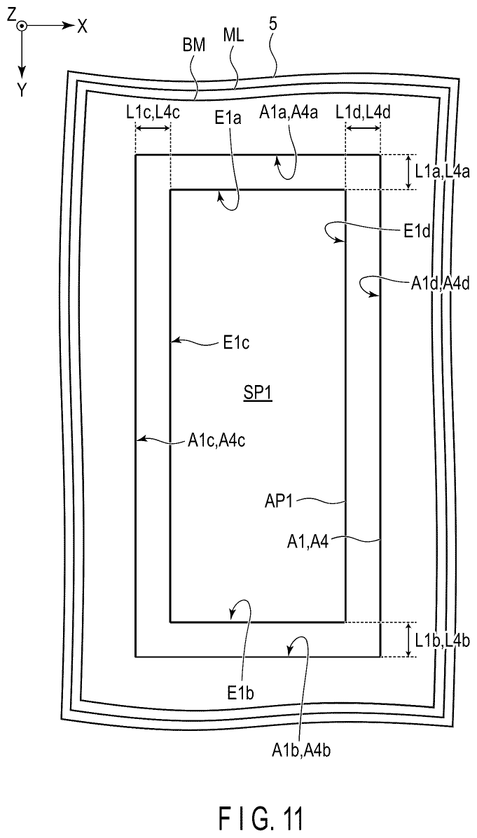

FIG. 11 is a schematic plan view showing an example of the pixel aperture AP1, the aperture A1 of the light-shielding film BM, and the aperture A4 of the metal wire ML. The pixel aperture AP1 and the apertures A1 and A4 overlap one another in plan view.

In the example of FIG. 11, the edge A1a overlaps the edge A4a in plan view. Similarly, the edge A1b overlaps the edge A4b in plan view, the edge A1c overlaps the edge A4c in plan view, and the edge

A1d overlaps the edge A4d in plan view. That is, the apertures A1 and A4 have the same area, and the periphery of the aperture A1 coincides with the periphery of the aperture A4 in plan view. Therefore, the distances L1a and L4a have the same length (L1a=L4a), the distances L1b and L4b have the same length (L1b=L4b), the distances L1c and L4c have the same length (L1c=L4c), and the distances L1d and L4d have the same length (L1d=L4d).

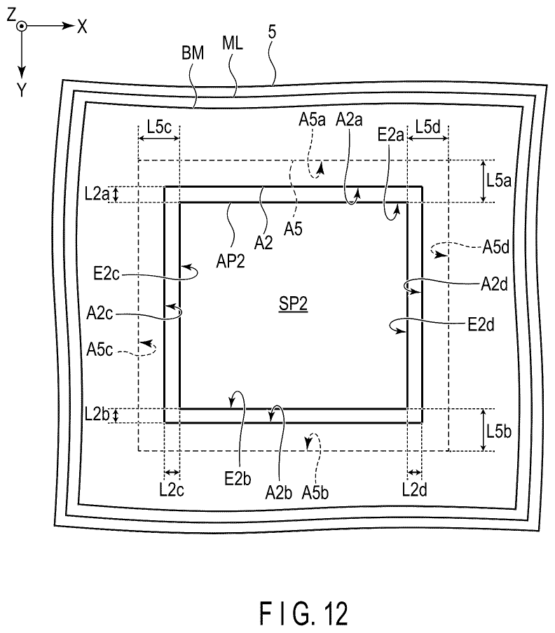

FIG. 12 is a schematic plan view showing an example of the pixel aperture AP2, the aperture A2 of the light-shielding film BM, and the aperture A5 of the metal wire ML. The pixel aperture AP2 and the apertures A2 and A5 overlap one another in plan view.

In the example of FIG. 12, the edge A2a is located between the edge E2a and the edge A5a in the Y direction. Similarly, the edge A2b is located between the edge E2b and the edge A5b in the Y direction, the edge A2c is located between the edge E2c and the edge A5c in the X direction, and the edge A2d is located between the edge E2d and the edge A5d in the X direction. That is, the area of the aperture A5 is greater than the area of the aperture A2, and the peripheries A5a to A5d of the aperture A5 overlap the light-shielding film BM in plan view. Therefore, the distance L2a is shorter than the distance L5a (L2a <L5a), the distance L2b is shorter than the distance L5b (L2b<L5b), the distance L2c is shorter than the distance L5c (L2c<L5c), and the distance L2d is shorter than the distance L5d (L2d<L5d).

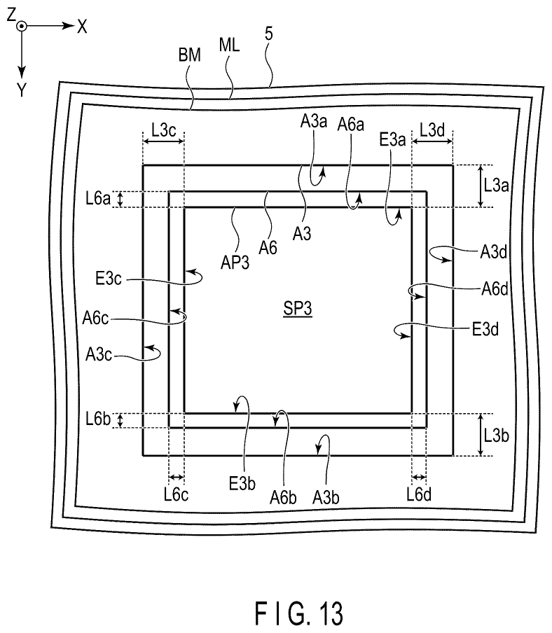

FIG. 13 is a schematic plan view showing an example of the pixel aperture AP3, the aperture A3 of the light-shielding film BM, and the aperture A6 of the metal wire ML. The pixel aperture AP3 and the apertures A3 and A6 overlap one another in plan view.

In the example of FIG. 13, the edge A6a is located between the edges E3a and A3a in the Y direction. Similarly, the edge A6b is located between the edge E3b and the edge A3b in the Y direction, the edge A6c is located between the edge E3c and the edge A3c in the X direction, and the edge A6d is located between the edge E3d and the edge A3d in the X direction. That is, the area of the aperture A3 is greater than the area of the aperture A6, and the peripheries A3a to A3d of the aperture A3 overlap the metal wire ML in plan view. Therefore, the distance L3a is longer than the distance L6a (L3a>L6a), the distance L3b is longer than the distance L6b (L3b>L6b), the distance L3c is longer than the distance L6c (L3c>L6c), and the distance L3d is longer than the distance L6d (L3d>L6d).

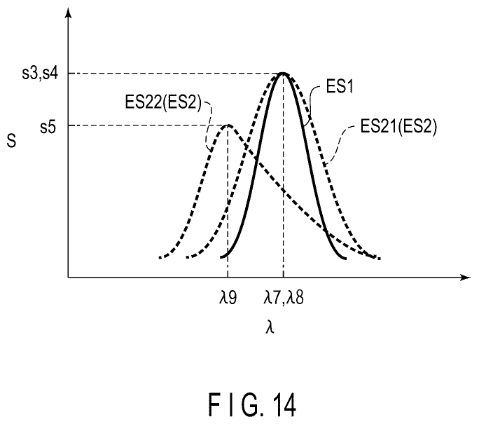

FIG. 14 shows an example of emission spectra. A graph in FIG. 14 has a horizontal axis indicative of wavelengths λ and a vertical axis indicative of spectrum strengths S. For example, FIG. 14 shows blue spectra emitted by the light emitting layer EM1 shown in FIG. 4. The emission spectra include an internal emission spectrum ES1 and an interference spectrum ES2. The internal emission spectrum ES1 depends on emitting materials of the light emitting layer EM1. The interference spectrum ES2 depends on refractive indexes and thicknesses of function layers and the cap layer CP. An interference spectrum ES21 shown in FIG. 14 corresponds to the interference spectrum ES2 in a case where the display device DSP is seen from the front. An interference spectrum ES22 corresponds to the interference spectrum ES2 in a case where the display device DSP is obliquely seen.

In the example of FIG. 14, a spectrum strength s4, the maximum value of the interference spectrum ES21, is the same as a spectrum strength s3, the maximum value of the internal emission spectrum ES1 (s4=s3). In addition, a wavelength λ8 of the inference spectrum ES21 at the spectrum strength s4 is the same as a wavelength λ7 of the internal emission spectrum ES1 at the spectrum strength s3 (λ8=>λ7). On the other hand, a spectrum strength s5, the maximum value of the inference spectrum ES22, is smaller than the spectrum strength s4, the maximum value of the interference spectrum ES21 (s5<s4). In addition, a wavelength λ9 of the interference spectrum ES22 at the spectrum strength s5 is smaller than the wavelength λ8 of the internal emission spectrum ES21 at the spectrum strength s4 (λ9<>λ8). That is, when the display device DSP is seen obliquely, a wavelength λ of the interference spectrum ES2 changes and then the spectrum strength S decreases.

Values of brightness of light beams emitted from the display device DSP are affected by wavelengths A of the internal emission spectrum ES1 and the interference spectrum ES2 and spectrum strengths S. That is, as the display device DSP is seen more obliquely, the amount of changes in a wavelength λ of the interference spectrum ES2 increases as described above. This decreases the spectrum strength S and thus decreases the brightness. For example, shifting the interference spectrum ES21 to the long-wave length direction (the right direction in the figures) can suppress decreases in brightness irrespective of changes in the angles at which the display device DSP is seen. However, this shifting displaces the wavelength λ7 of the internal spectrum ES1 and the wavelength λ8 of the interference emission spectrum ES21 from each other. This displacement may reduce the brightness in cases where the display device DSP is shown from the front.

The above description on the emission spectrum of the light emitting layer EM1 applies to the emission spectra of the light emitting layers EM2 and EM3 as well. As shown in FIG. 5, the internal emission spectra of the light emitting layers EM1, EM2, and EM3 are different from one another. Therefore, when the display device DSP is obliquely seen, the light emitting layers EM1, EM2, and EM3 have different values of: the wavelengths A of the interference spectrum ES2, the amount of changes in the spectrum strengths S, and the values of brightness of light beams emitted from the display device DSP.

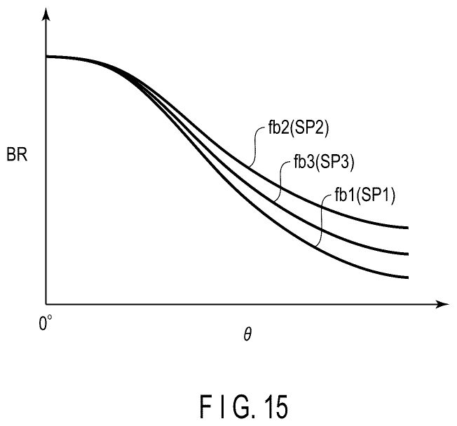

FIG. 15 is a diagram showing relationships between angles θ and values of brightness BR of the subpixels SP1, SP2, and SP3. A graph in FIG. 15 has a horizontal axis showing angles θ with respect to the axis parallel to the Z direction and a vertical axis showing values of brightness BR in cases where the display device DSP is seen at these angles. Curved lines fb1, fb2, and fb3 indicate respective values of brightness of the subpixels SP1, SP2, and SP3 at a given angle. The angle θ at the origin indicates 0°. As shown in FIG. 15, the subpixels SP1, SP2, and SP3 have essentially the same brightness when the angle θ is 0°.

As described with reference to FIG. 5, the half width FW3 of the internal emission spectrum of the light emitting layer EM3 is greater than the half width FW1 of the internal emission spectrum of the light emitting layer EM1 and is smaller than the half width FW2 of the internal emission spectrum of the light emitting layer EM2 (FW1<FW3<FW2). As the angle θ increases, the maximum spectrum strength s5, the maximum strength of the inference spectrum ES22, and the wavelength λ9 of the interference spectrum ES22 shown in FIG. 14 decrease. Thus, as the angle θ increases, the brightness BR of the subpixel SP1 attenuates more greatly than the brightness BR of the subpixel SP2 and the subpixel SP3 do. The brightness BR of the subpixel SP2 attenuates more gradually than the brightness of the subpixels SP1 and SP3 do. Except 0°, at any given angle θ, the brightness BR of the subpixel SP3 is greater than the brightness BR of the subpixel SP1 and is smaller than the brightness BR of the subpixel SP2 (the brightness BR of the subpixel SP1<the brightness BR of the subpixel SP3<the brightness BR of the subpixel SP2). Thus, as the display device DSP is seen more obliquely, the color displayed in the display device DSP changes. This configuration is disadvantageous.

Next, an effect of the present embodiment will be described.

In the present embodiment, the respective distances L2a to L2d between the edges E2a to E2d of the pixel aperture AP2 that overlaps the subpixel SP2 and the edges A2a to A2d of the aperture A2 of the light-shielding film BM are smaller than the respective distances L1a to L1d between the edges E1a to E1d of the pixel aperture AP1 that overlaps the subpixel SP1 and the edges A1a to A1d of the aperture A1 of the light-shielding film BM. In the present embodiment, the respective distances L6a to Led between the edges E3a to E3d of the pixel aperture AP3 that overlaps the subpixel SP3 and the edges A6a to A6d of the aperture A6 of the metal wire ML are smaller than the respective distances L4a to L4d between the edges E1a to E1d of the pixel aperture AP1 that overlaps the subpixel SP1 and the edges A4a to A4d of the aperture A4 of the metal wire ML. This configuration has the light-shielding film BM partially blocking light beams emitted from the subpixel SP2 and thus reduces the brightness BR of the subpixel SP2. Further, this configuration has the metal wire ML partially blocking light beams emitted from the subpixel SP3 and thus reduces the brightness BR of the subpixel SP3. In contrast, light beams emitted from the subpixel SP1 are less susceptible to blocking by the light-shielding film BM than light beams emitted from the subpixels SP2 and SP3. In the graph shown in FIG. 15, the values of brightness BR of the subpixel SP2 and the subpixel SP3 decrease such that the curved lines fb2 and fb3 approach the curved line fb1. This configuration decreases the differences in the values of brightness BR among the subpixels SP1, SP2, and SP3 at a given angle θ. That is, a color displayed in the display device DSP is less likely to change even when the given angle θ changes. Thus, display qualities of the display device DSP can be increased.

For example, when only the metal wire ML is used to make the brightness of the subpixel SP2 equivalent to the brightness of the subpixel SP1, the edges A5a to A5d of the aperture A5 may overlap the pixel aperture AP2 in plan view. This overlapping configuration involves the metal wire ML partially blocking light beams emitted from the subpixel SP2 and may decrease the brightness of the display device DSP when it is seen from the front.

The present embodiment has the light-shielding film BM farther from the light emitting layers EM1, EM2, and EM3 in the Z direction than the metal wire ML is. As the light-shielding film BM and the metal wire ML become farther from the light emitting layers EM1, EM2, and EM3 in the Z direction, the blocked amount of light beams emitted from the light emitting layers EM1, EM2, and EM3 by the light-shielding film BM and the metal wire ML increases. That is, when a required light blocked amount is small and the edges A4a to A6d of the apertures A4, A5, and A6 of the metal wire ML do not overlap the pixel apertures AP1, AP2, and AP3 in plan view, light beams are blocked by the metal wire ML that is close to the light emitting layers EM1, EM2, and EM3. In contrast, when a required light blocked amount is large and the edges A4a to A6d of the apertures A4, A5, and A6 of the metal wire ML overlap the pixel apertures AP1, AP2, and AP3 in plan view, light beams are blocked by the light-shielding film BM that is far from the light emitting layers EM1, EM2, and EM3. This configuration can ensure a sufficient light blocked amount without decreasing the brightness of the display device DSP when it is seen from the front.

The present embodiment has described the case where the light-shielding film BM and the metal wire ML function as the light-shielding films that block light beams emitted from the light emitting layers EM1, EM2, and EM3. However, other light-shielding components may function as the light-shielding films. The light-shielding film may be composed of three or more light-shielding components or a single light-shielding component as in the second embodiment and the third embodiment to be described later.

In the above descriptions, when the X direction corresponds to the first direction and the Y direction corresponds to the second direction, the edges E1a and E1b correspond to the first edges, the edges E2a and E2b correspond to the second edges, the edges A1a and A1b correspond to the third edges, the edges A2a and A2b correspond to the fourth edges, the edges E3a and E3b correspond to the fifth edges, the edges A3a and A3b correspond to the sixth edges, the edges A4a and A4b correspond to the seventh edges, the edges A5a and A5b correspond to the eighth edges, and the edges A6a and A6b correspond to the ninth edges.

Further, when the X direction corresponds to the second direction and the Y direction corresponds to the first direction, the edges E1c and E1d correspond to the first edges, the edges E2c and E2d correspond to the second edges, the edges A1c and A1d correspond to the third edges, the edges A2c and A2d correspond to the fourth edges, the edges E3c and E3d correspond to the fifth edges, the edges A3c and A3d correspond to the sixth edges, the edges A4c and A4d correspond to the seventh edges, the edges A5c and A5d correspond to the eighth edges, and the edges A6c and A6d correspond to the ninth edges.

Further, when the subpixel SP1 illuminating in blue corresponds to the first subpixel, the subpixel SP2 illuminating in green or the subpixel SP3 illuminating in red corresponds to the second subpixel. Further, when the subpixel SP3 illuminating in red corresponds to the first subpixel, the subpixel SP2 illuminating in green corresponds to the second subpixel.

### Second Embodiment

Next, the second embodiment will be described. Except configurations described below, the second embodiment has the same configurations as the first embodiment.

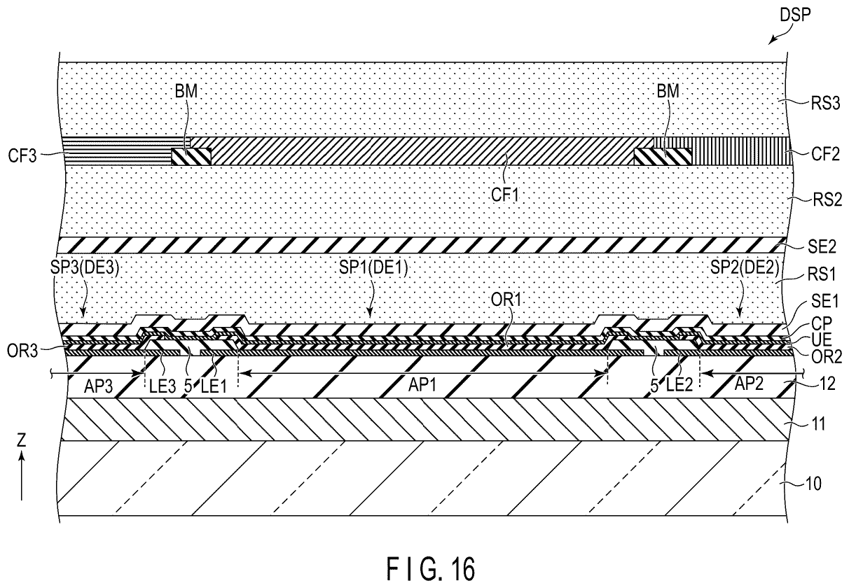

FIG. 16 is a schematic cross-sectional view of a display device DSP of the second embodiment. The display device DSP of the second embodiment shown in FIG. 16 is different from the display device DSP of the first embodiment in not comprising the metal wire ML shown in FIG. 3.

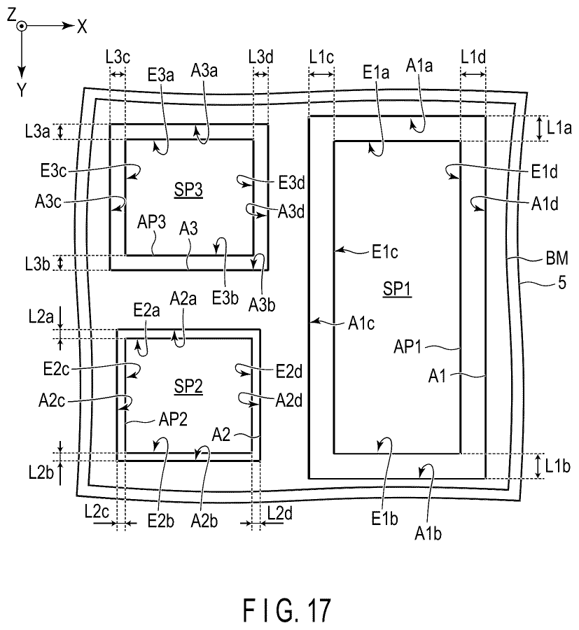

FIG. 17 is a schematic plan view showing a layout example of pixel apertures AP1, AP2, and AP3 and apertures A1, A2, and A3 of a light-shielding film BM of the second embodiment. In the example of FIG. 17, a distance L3a is shorter than a distance L1a, a distance L2a is shorter than the distance L3a (L2a<L3a<L1a). Similarly, a distance L3b is shorter than a distance

L1b, a distance L2b is shorter than the distance L3b (L2b<L3b<L1b). Further, a distance L3c is shorter than a distance L1c, a distance L2c is shorter than the distance L3c (12c<L3c<L1c). Further, a distance L3d is shorter than a distance L1d, a distance L2d is shorter than the distance L3d (L2d<L3d<L1d).

As shown in FIG. 16 and FIG. 17, the same effect as the above-described effect can be obtained even by a layer functioning as the light-shielding film.

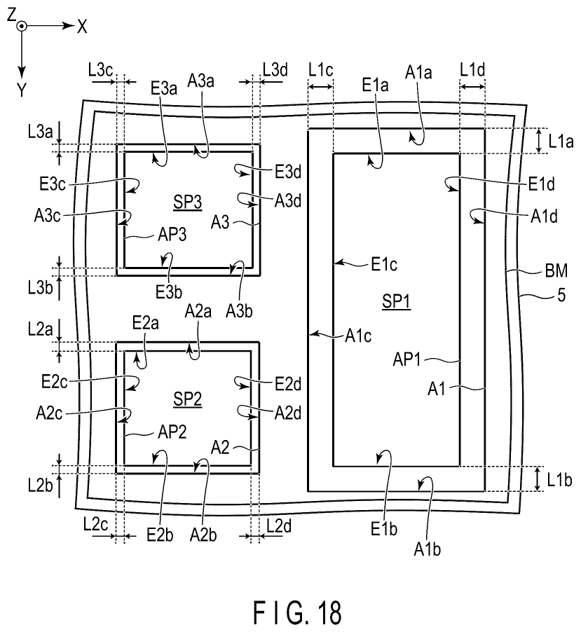

FIG. 18 is a schematic plan view showing another example of the pixel apertures AP1, AP2, and AP3 and the apertures A1, A2, and A3 of the light-shielding film BM of the second embodiment. In

FIG. 18, the distances L2a and L3a have the same length (L2a =L3a). Similarly, the distances L2b and L3b have the same length (L2b=L3b), the distances L2c and L3c have the same length (L2c=L3c), and the distances L2d and L3d have the same length (L2d=L3d).

The configuration shown in FIG. 18 enables subpixels SP2 and SP3 having the essentially same values of brightness, for example, when a half width FW2 of a light emitting layer EM2 and a half width FW3 of a light emitting layer EM3 shown in FIG. 5 are the same. Thus, the configuration of FIG. 18 can achieve the same effect as the above-described effect.

### Third Embodiment

Next, the third embodiment will be described. Except configurations described below, the third embodiment has the same configurations as the first embodiment and the second embodiment.

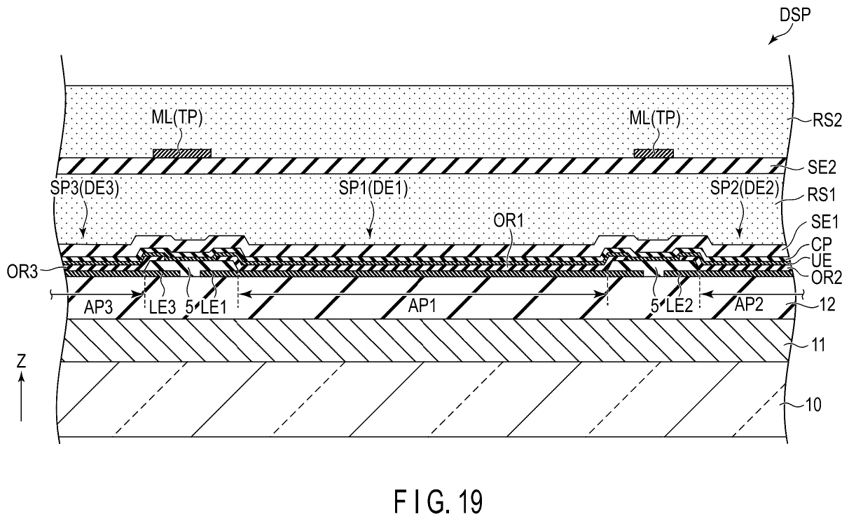

FIG. 19 is a schematic cross-sectional view showing a display device DSP of the third embodiment. The display device DSP of the third embodiment shown in FIG. 19 is different from the display device DSP of the first embodiment in not comprising the color filters CF1, CF2, and CF3, the light-shielding film BM, and the resin layer RS3 shown in FIG. 3. For example, a polarizer may be attached to the top surface of the resin layer RS2 via adhesion layers such as OCA.

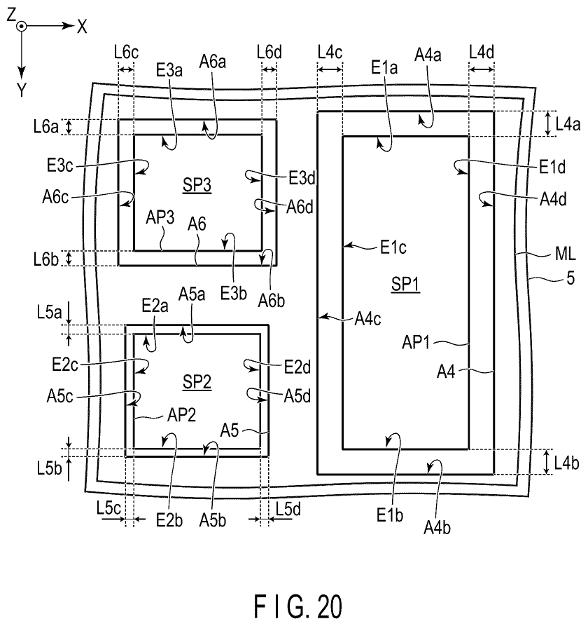

FIG. 20 is a schematic plan view showing a layout example of pixel apertures AP1, AP2, and AP3, and apertures A4, A5, and A6 of a metal wire ML of the third embodiment. In the example of FIG. 20, a distance L6a is shorter than a distance L4a, a distance La is shorter than the distance L6a (L5a<L6a<L4a). Similarly, a distance L6b is shorter than a distance L4b, a distance L5b is shorter than the distance L6b (L5b<L6b<L4b). Further, a distance L6c is shorter than a distance L4c, a distance L5c is shorter than the distance L6c (L5c<L6c<L4c). Further, a distance L6d is shorter than a distance L4d, a distance L5d is shorter than the distance L6d (L5d<L6d<L4d).

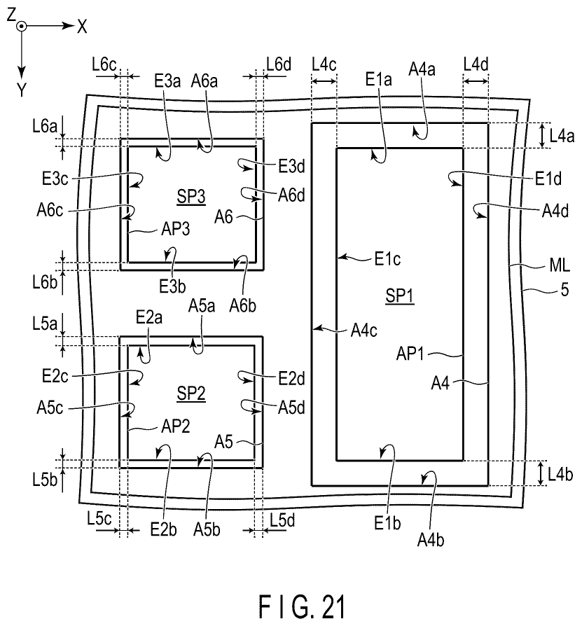

FIG. 21 is a schematic plan view showing another example of the pixel apertures AP1, AP2, and AP3, and the apertures A4, A5, and A6 of the metal wire ML of the third embodiment. In FIG. 21, the distances L5a and L6a have the same length (L5a=L6a). Similarly, the distances L5b and L6b have the same length (L5b=L6b), the distances L5c and L6c have the same length (L5c=L6c), and the distances L5d and L6d have the same length (L5d=L6d).

Thus, the configurations of FIG. 19, FIG. 20, and FIG. 21 can achieve the same effect as the above-described effect.

All of the display devices that can be implemented by a person of ordinary skill in the art through arbitrary design changes to the display device described above as the embodiment of the present invention come within the scope of the present invention as long as they are in keeping with the spirit of the present invention.

Various types of the modified examples are easily conceivable within the category of the ideas of the present invention by a person of ordinary skill in the art. The modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
a first subpixel and a second subpixel that are spaced apart from each other and illuminate in colors different from each other;
a rib layer; the rib layer including:
a first pixel aperture, which has a first edge parallel to a first direction and overlaps the first subpixel; and
a second pixel aperture, which has a second edge parallel to the first direction and overlaps the second subpixel; and
a first light-shielding film located above the rib layer, the first light-shielding film including:
a first aperture, which has a third edge parallel to the first direction and overlaps the first pixel aperture; and
a second aperture, which has a fourth edge parallel to the first direction and overlaps the second pixel aperture, wherein
a distance between the second edge and the fourth edge along a second direction intersecting the first direction is shorter than a distance between the first edge and the third edge along the second direction.

2. The display device of claim 1, wherein
a half width of an internal emission spectrum of a light emitting layer included in the first subpixel is smaller than a half width of an internal emission spectrum of a light emitting layer included in the second subpixel.

3. The display device of claim 1, wherein
the first subpixel illuminates in blue, and
the second subpixel illuminates in green.

4. The display device of claim 1, wherein
the first subpixel illuminates in blue, and
the second subpixel illuminates in red.

5. The display device of claim 1, wherein
the first subpixel illuminates in red, and
the second subpixel illuminates in green.

6. The display device of claim 1, further comprising:
a color filter located above the rib layer, wherein
the first light-shielding film contacts the color filter.

7. The display device of claim 1, wherein
the first light-shielding film is composed of a metal material.

8. The display device of claim 1, further comprising:
a third subpixel spaced apart from the first
subpixel and the second subpixel and illuminating in a color different from the colors of the first subpixel and the second subpixel, wherein
the rib layer further includes a third pixel aperture, which has a fifth edge parallel to the first direction and overlaps the third subpixel,
the first light-shielding film further includes a third aperture, which has a sixth edge parallel to the first direction and overlaps the third pixel aperture, and
a distance between the fifth edge and the sixth edge along the second direction is shorter than a distance between the first edge and the third edge along the second direction.

9. The display device of claim 8, wherein
a distance between the fifth edge and the sixth edge along the second direction is longer than or equal to a distance between the second edge and the fourth edge along the second direction.

10. The display device of claim 1, further comprising:
a second light-shielding film located between the rib layer and the first light-shielding film and overlapping the rib layer and the first light-shielding film.

11. The display device of claim 10, further comprising:
a color filter located above the rib layer, wherein
the first light-shielding film contacts the color filter.

12. The display device of claim 10, wherein
the second light-shielding film is composed of a metal material.

13. The display device of claim 10, further comprising:
a resin layer located between the first light-shielding film and the second light-shielding film.

14. The display device of claim 13, wherein
the resin layer contacts the first light-shielding film and the second light-shielding film.

15. The display device of claim 10, further comprising:
a third subpixel spaced apart from the first subpixel and the second subpixel and illuminating in a color different from the colors of the first subpixel and the second subpixel, wherein
the rib layer further includes a third pixel aperture, which has a fifth edge parallel to the first direction and overlaps the third subpixel,
the first light-shielding film further includes a third aperture, which has a sixth edge parallel to the first direction and overlaps the third pixel aperture,
the second light-shielding film includes:
a fourth aperture, which has a seventh edge parallel to the first direction and overlaps the first pixel aperture and the first aperture;
a fifth aperture, which has an eighth edge parallel to the first direction and overlaps the second pixel aperture and the second aperture; and
a sixth aperture, which has a ninth edge parallel to the first direction and overlaps the third pixel aperture and the third aperture, and
a distance between the fifth edge and the ninth edge along the second direction is shorter than a distance between the first edge and the seventh edge along the second direction.

16. The display device of claim 15, wherein
a distance between the fifth edge and the sixth edge along the second direction is longer than a distance between the fifth edge and the ninth edge along the second direction.

17. The display device of claim 15, wherein
a distance between the second edge and the fourth edge along the second direction is shorter than a distance between the fifth edge and the sixth edge along the second direction.

18. The display device of claim 8, wherein
a half width of an internal emission spectrum of a light emitting layer included in the first subpixel is smaller than a half width of an internal emission spectrum of a light emitting layer included in the second subpixel and a half width of an internal emission spectrum of a light emitting layer included in the third subpixel.

19. The display device of claim 8, wherein
a half width of an internal emission spectrum of a light emitting layer included in the third subpixel is greater than a half width of an internal emission spectrum of a light emitting layer included in the first subpixel and is smaller than a half width of an internal emission spectrum of a light emitting layer included in the second subpixel.

20. The display device of claim 8, wherein
the first subpixel illuminates in blue,
the second subpixel illuminates in green, and
the third subpixel illuminates in red.
